(19) United States
(12) Patent Application Publication
(10) Pub. No.: US 2001/0045653 A1
(43) Pub. Date: Nov. 29, 2001

(54) APPARATUS AND METHOD FOR METAL LAYER STRECHED CONDUCTING PLUGS

(76) Inventor: SUDHIR K. MADAN, DALLAS, TX (US)

Correspondence Address: TEXAS INSTRUMENTS INCORPORATED, P O BOX 655474, M/S 3999, DALLAS, TX, 75265

(21) Appl. No.: 09/311,502

(22) Filed: May 13, 1999

Related U.S. Application Data
(60) Provisional application No. 60/086,437, filed on May 22, 1998.

(51) Int. Cl. H01L 23/48

(52) U.S. Cl. 257/754; 257/763; 257/774

(57) ABSTRACT

To provide a conducting path between the metal_0 layer and a metal_1 interconnect layer, two layers with conducting plugs were necessary in the prior art. In the present invention, the conducting regions electrically coupling two regions of the integrated circuit are formed at the same time as the formation of the conducting plugs coupling selected portions of the integrated circuit with the metal_1 interconnect layer. The conducting regions, as with the conducting plugs, extend to surface of the insulating layer upon which the metal_1 interconnect paths are patterned. Using this technique, process steps required in the prior art can be eliminated. This process has the limitation that the metal_1 interconnect layer can not be formed over the conducting regions.

### BACKGROUND OF THE INVENTION

1. Field of the Invention

This invention relates generally to integrated circuits and, more particularly, to the layers of conducting paths that are used to connect electrically selected regions of the circuit.

2. Description of the Prior Art

In order to increase the circuit density, damascene tungsten technology is currently being implemented to form the layer of conducting paths electrically coupling moat and gate electrodes, this layer of conducting paths generally being referred to as Metal_{—}0. The next conducting path metal layer, generally referred to a Metal_{—}1, is electrically coupled to the Metal_{—}0 layer by means of holes or vias formed in an intervening dielectric layer, that are filled with a conducting material. The procedure to form the Metal_{—}0 layer requires an additional masking step when compared to a integrated circuit which does not require a procedure for including the Metal_{—}0 layer.

Referring to FIG. 1A through FIG. 1C, the prior art technique for providing a Metal_{—}0 conducting path between adjacent regions is illustrated. In FIG. 1A, several of the steps in the fabrication of semiconductor device have been completed. The n+ doped regions 5, silicide layers 6, and shallow trench isolation regions 4 have been formed in the substrate 2. A polysilicon region 8 formed over a portion of the trench isolation region 4 is shown in FIG. 1A through FIG. 1C. The polysilicon region 8 is enclosed by a silicide layer 7 and by insulator sidewalls 9. A silicon nitride layer 11 and silicon oxide layer 12 is formed. The oxide layer 12 is planarized. In FIG. 1B, vias are etched through the silicon oxide layer 12, through the silicon nitride layer 11 until selected portions of the silicide layers 6 and 7 are exposed. The vias are lined with titanium nitride 13 and filled with tungsten. The structure is planarized to expose the silicon oxide layer 12, and the resulting conducting plugs 14 and 14′ are called first plugs. As shown in FIG. 1B, one of the first conducting plugs 14′ is expanded to expose conducting areas from a silicide region over moat 6 to a silicide region over the polysilicon region 7 and therefore the conducting plug 14′ provides and electrical short circuit between the moat region 6 and the polysilicon region 7. In FIG. 1C, again combining several steps, a second oxide layer 15 is formed over the first oxide layer 12 and the conducting plugs 14. Vias are formed in the oxide layer 15, exposing conducting plugs 14. The vias filled with tungsten and the structure planarized to expose oxide layer 15, resulting in conducting plugs 16. The resulting conducting plugs 16 are generally referred to as the second conducting plugs. Next an aluminum layer 17 is formed on oxide layer 15 and the second plugs 16. The aluminum layer 17 is patterned to provide conducting paths 17 electrically coupling selected silicide regions 6 and 7 through conducting plugs 14 and conducting plugs 16 to form the metal_{—}1 (interconnect) layer. Note that this prior art scheme allows metal conducting paths 17 to be positioned over plugs 14 (over plug 14′ without shorting it by not having a plug 16 between metal conducting paths 17 and the plug 14′. Because of the complexity of the interconnections required between the integrated circuit elements, additional metal layers must typically be added to provide the requisite conducting paths between the integrated circuit elements.

As will be clear to those skilled in the art, a need has been felt for a technique to reduce the number of process steps required to implement the interconnect structure.

### SUMMARY OF THE INVENTION

The aforementioned and other features are accomplished, according to the present invention, by eliminating the requirement for the second metal plugs, thereby reducing the number of process steps to fabricate the structure.

These and other features of the present invention will be understood upon the reading of the following description in conjunction with the Figures.

### BRIEF DESCRIPTION OF THE DRAWINGS

FIG. 1A, FIG. 1B, and FIG. 1C illustrate the fabrication of an interconnect structure according to the prior art.

FIG. 2A, FIG. 2B, and FIG. 2C illustrate the fabrication of an interconnect structure according to the present invention.

### DESCRIPTION OF THE PREFERRED EMBODIMENT(S)

1. Detailed Description of the Drawings

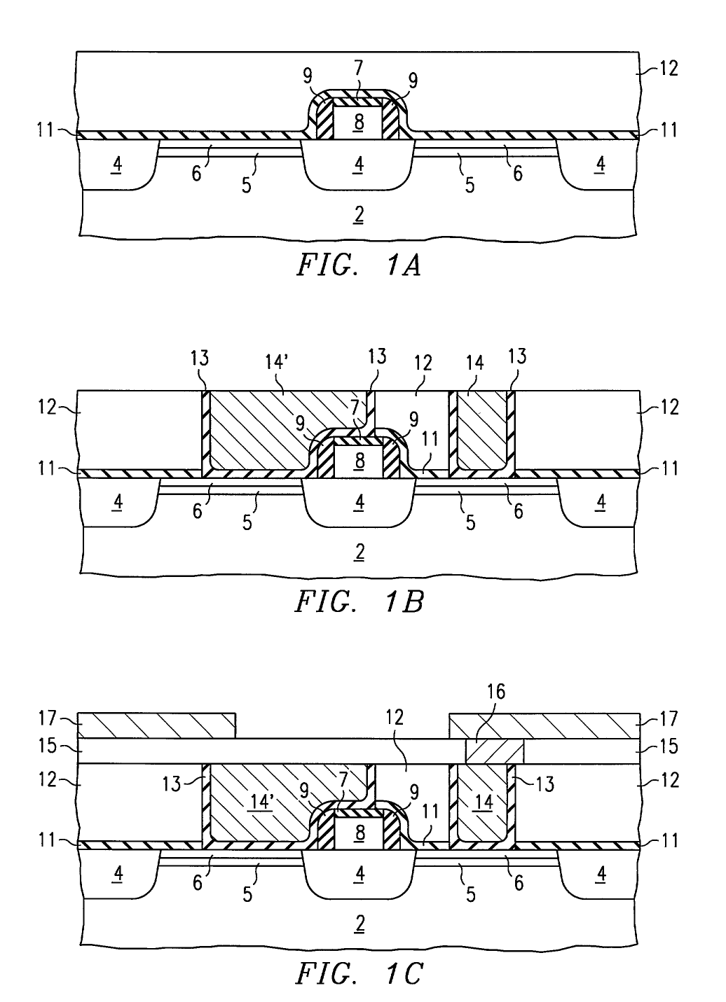

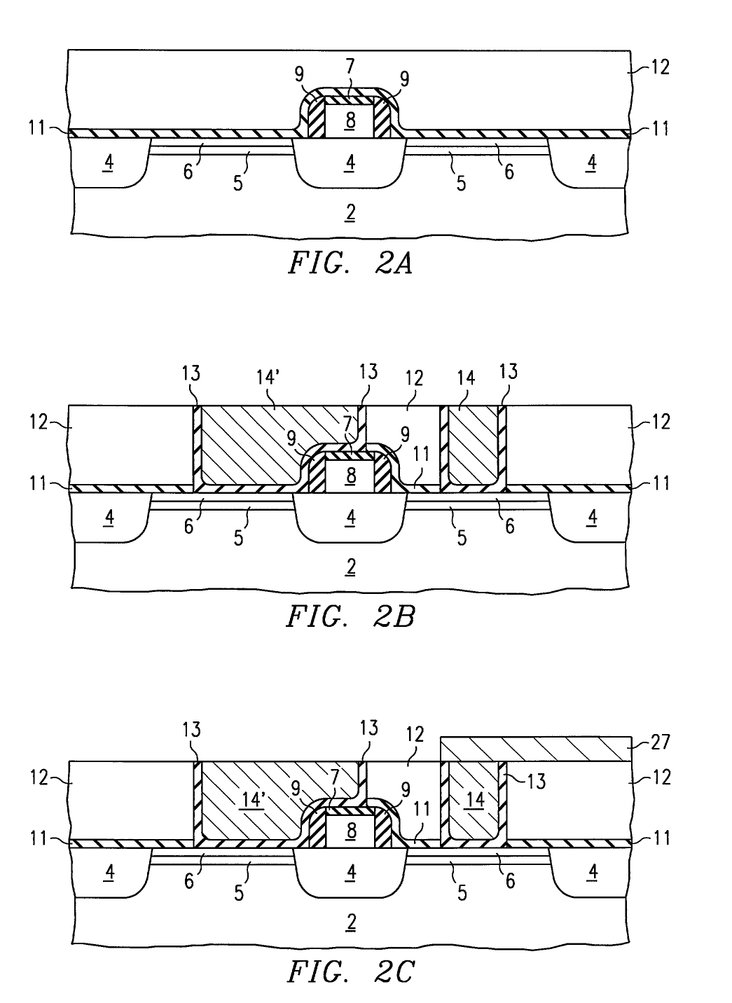

Referring to FIG. 2A through FIG. 2C, the technique for fabricating an interconnect structure, according to the present invention, is shown. FIG. 2A and FIG. 2B replicate FIG. 1A and FIG. 1B, respectively. The process shown in FIG. 2C illustrates the divergence from the prior art. In FIG. 2C, the conducting plugs 14 and 14′ and the oxide layer 12 are planarized. Thereafter, an aluminum layer 27 is formed and patterned to provide the metal_{—}1 interconnect layer.

2. Operation of the Preferred Embodiment(s)

Comparing FIG. 1C and to FIG. 2C, the present invention eliminates the need for a second oxide layer 15 and the associated conducting plugs 16. The conducting region 14′ becomes a sketched (as compared to 14) conducting plug. However, this elimination of processing steps is provided at the expense of a limitation in the patterning of the metal_{—}1 layer 27. Specifically, the metal_{—}1 layer 27 conducting paths are not permitted on the exposed portion of plug 14′.

While the invention has been described with particular reference to the preferred embodiment, it will be understood by those skilled in the art that various changes may be made and equivalents substituted for elements of the preferred embodiment without departing from the invention. In addition, many modifications may be made to adapt a particular situation and material to a teaching of the present invention without departing from the essential teachings of the present invention. For example, the substrate region can be fabricated from silicon or any other suitable insulating material. Similarly, the isolated conducting regions that the expanded conducting plug electrically couples can be diffused regions, gate regions, silicided diffused regions, silicided gates and metal regions or combinations thereof. The first conducting layer, i.e., the layer with the expanded conducting plugs can be comprised of at least one conducting material selected from the group that includes titanium, titanium nitride, tungsten, aluminum, and copper. The second conducting layer, i.e., the metal_{—}1 layer, can be comprised of at least one of the conducting material selected from the group consisting of titanium, titanium nitride, tungsten, aluminum and copper. As will be clear to those skilled in the art, planarization of specified layers can be accomplished by various techniqes, for example, by chemical mechanical polishing (CMP), by an etch-back process, etc.

As is evident from the foregoing discussion, certain aspects of the invention are not limited to the particular details of the examples illustrated, and it is therefore contemplated that other modifications and applications will occur to those skilled in the art. It is accordingly intended that the claims shall cover all modifications and applications as do not depart from the spirit and scope of the invention.

What is claimed is:

1. A metal interconnect structure for providing a conducting path between electrically isolated conducting regions in an integrated circuit, said conducting regions having an insulating layer formed thereon, said structure comprising:
a first conducting layer comprising a plurality of conducting plugs of first conducting material formed through said insulating layer, said plugs forming an electrical contact with said electrically isolated conducting regions, wherein at least one of said plugs forms an electrical contact with at least two of said isolated conducting regions; and
a patterned layer of a second conducting material formed on said insulating layer, said patterned layer electrically coupling selected plugs.

2. The structure of claim 1 further comprising:
a second insulating layer over said patterned layer;
a second plurality of conducting plugs formed through said second insulating layer, said second plurality of conducting plugs electrically contacting selected regions of said patterned layer; and
a second patterned layer of conducting material formed on said second insulating layer, said second patterned electrically layer electrically coupling selected second plurality of conducting plugs.

3. The structure of claim 1 wherein a substrate, upon which said integrated circuit is formed, is comprised of silicon.

4. The structure of claim 1 wherein a substrate, upon which said integrated circuit is formed, is comprised of an insulating layer.

5. The structure of claim 1 wherein said isolated conducting regions are comprised of diffused regions, gate regions, silicided diffused regions, silicided gate regions and metal regions or combinations thereof.

6. The structure of claim 1 wherein said first conducting layer comprises at least one sublayer, each sublayer including at least one material selected from the group consisting of titanium. Titanium nitride, tungsten, aluminum, and copper.

7. The structure of claim 1 in which said first patterned layer consists of at least one material selected from the group consisting of titanium, titanium nitride, tungsten, aluminum, and copper.

8. The method of forming a metal interconnect structure in an integrated circuit device, said integrated circuit device having a electrically conducting isolated regions formed thereon, said method comprising the steps of:
forming an insulating layer on said electrically conducting isolated regions;
forming holes through said insulating layer exposing selected electrically conducting isolated regions, wherein at least one of the holes exposes at least two electrically conducting isolated regions;
forming a first conducting layer by filling said holes with a conducting material to form conducting plugs;
forming and patterning a second conducting layer on said first conducting layer and said insulating layer, said second conducting layer electrically coupling preselected conducting plugs.

9. The method of claim 8 further comprising the steps of
forming a second insulating layer over said insulating layer and said second conducting layer;
forming holes in said second insulating layer to expose predetermined regions of said second conducting regions;
filling said holes to form second conducting plugs, said conducting plugs electrically contacts said predetermined regions; and
forming and patterning a third conducting layer on said second insulating layer and said second conducting plugs, said third conducting layer electrically coupling preestablished second conducting plugs.

10. The method of claim 8 further comprising the step of fabricating a substrate, upon which said integrated circuit is formed, from silicon.

11. The method of claim 8 further comprising the step of fabricating a substrate, upon which said integrated circuit is formed, from an insulating material.

12. The method of claim 8 further comprising the step of fabricating said isolated conducting regions from at least one of the group consisting of diffused regions, gate regions, silicided diffused regions, silicided gates regions, and metal regions.

13. The method of claim 8 wherein said step of forming a first conducting layer includes the step of forming said first conducting layer by forming at least one layer from the group of materials consisting of titanium, titanium nitride, tungsten, aluminum, and copper.

14. The method of claim 8 wherein said the step of fabricating said second conducting layer includes the step of fabricating said second conducting layer from at least one of the group of materials consisting of titanium, titanium nitride, tungsten, aluminum, and copper.
